(19) United States
(12) Patent Application Publication
(10) Pub. No.: US 2015/0064964 A1
(43) Pub. Date: Mar. 5, 2015

(54) Double Stack Compact Flash Card Connector

(71) Applicant: Brocade Communications Systems, Inc., San Jose, CA (US)

(72) Inventors: Scott W. Augsburger, San Jose, CA (US); Mark G. Siechen, Scotts Valley, CA (US); David A. Skirmont, Los Gatos, CA (US)

(21) Appl. No.: 14/536,283

(22) Filed: Nov. 7, 2014

Related U.S. Application Data
(62) Division of application No. 13/458,919, filed on Apr. 27, 2012, now abandoned.
(60) Provisional application No. 61/483,038, filed on May 5, 2011.

(51) Int. Cl. H01R 13/518; H05K 3/32; H01R 12/57

(52) U.S. Cl. CPC H01R 13/518; H01R 12/57; H05K 3/32
USPC 439/541.5; 29/832

(57) ABSTRACT

A first housing element is attached to an upper surface of a printed circuit board (PCB), and a second housing element is attached to a lower surface of the PCB. The first housing element receives a first electronic module, and includes a first signal wire that connects the first electronic module to a first trace on the PCB. The second housing element receives a second electronic module, which is vertically aligned with the first electronic module, and includes a second signal wire that connects the second electronic module to the first trace on the PCB. Alternately, a housing element attached to a PCB receives two or more electronic modules, and provides unique connections between the electronic modules and the PCB.

### RELATED APPLICATIONS

This application is a divisional application of U.S. patent application Ser. No. 13/458,919, filed Apr. 27, 2012, which claims priority from U.S. Provisional Patent Application Ser. No. 61/483,038, entitled “Double Stack Compact Flash Card Connector”, which was filed on May 5, 2011, and is incorporated by reference herein.

### FIELD OF THE INVENTION

The present invention relates to a connector that provides an interface between a printed circuit board (PCB) and a plurality of removable memory cards.

### RELATED ART

A conventional memory card connector is typically mounted on a surface of a printed circuit board (PCB), wherein the memory card connector includes a plurality of conductors that are placed in electrical contact with traces on the PCB. The memory card connector also includes a physical interface for receiving a memory card. In general, the memory card is inserted into the physical interface, thereby placing contact elements on the memory card into electrical contact with the conductors in the memory card connector. In this manner, the memory card is electrically connected to the PCB through the memory card connector. In general, memory card connector supports the memory card above the surface of the PCB.

As PCB component density increases, it becomes desirable to improve the density with which memory cards may be mounted on the PCB. It would therefore be desirable to have improved methods and structures for connecting a plurality of memory cards to a PCB, while minimizing the layout area of the PCB dedicated to the connection of these memory cards.

### SUMMARY

Accordingly, the present invention provides a housing element that allows two or more electronic modules, including, but not limited to, memory cards, to be stacked on top of one other to minimize the associated PCB footprint.

In one embodiment, a housing element is attached to a first surface of a PCB, wherein the housing element includes a first slot that receives a first electronic module and a second slot that receives a second electronic module. A first set of conductive elements extend through the housing element and couple the first electronic module to a first set of traces on the PCB. A second set of conductive elements, separate from the first set of conductive traces, extend through the housing element and couple the second electronic module to a second set of traces on the PCB. In a particular embodiment, all of the connections between the first electronic module and the PCB are separate from all of the connections between the second electronic module and the PCB. In accordance with another embodiment, the first and second electronic modules are vertically aligned with one another, and are positioned in parallel with the first surface of the PCB.

In an alternate embodiment, a first housing element is attached to an upper surface of a PCB, and a second housing element is attached to a lower surface of the PCB. The first housing element receives a first electronic module, and includes a first signal wire that connects the first electronic module to a first trace of the PCB. The second housing element receives a second electronic module, which is vertically aligned with the first electronic module, and includes a second signal wire that connects the second electronic module to the first trace of the PCB. In one embodiment, the first trace of the PCB includes a portion that extends vertically between the upper and lower surfaces of the PCB. In another embodiment, the connector elements of the first and second electronic modules are similarly oriented and vertically aligned.

The present invention will be more fully understood in view of the following description and drawings.

### BRIEF DESCRIPTION OF THE DRAWINGS

FIG. 1 is a cross sectional side view of a PCB system that implements a double-stacked memory card concept in accordance with one embodiment of the present invention.

FIG. 2 is a top view of the PCB system of FIG. 1 in accordance with one embodiment of the present invention.

FIG. 3 is a cross sectional side view of a PCB system that implements a double-stacked memory card concept in accordance with an alternate embodiment of the present invention.

FIG. 4 is an isometric view that illustrates the orientation of connector elements of double-stacked memory cards in accordance with one embodiment of the present invention.

FIG. 5 is a close-up view of signal lines used to couple the connector elements of similarly oriented double-stacked memory cards in accordance with one embodiment of the present invention.

FIG. 6 is a cross sectional side view of a PCB system that includes memory cards stacked on opposing sides of a printed circuit board in accordance with an alternate embodiment of the present invention.

### DETAILED DESCRIPTION

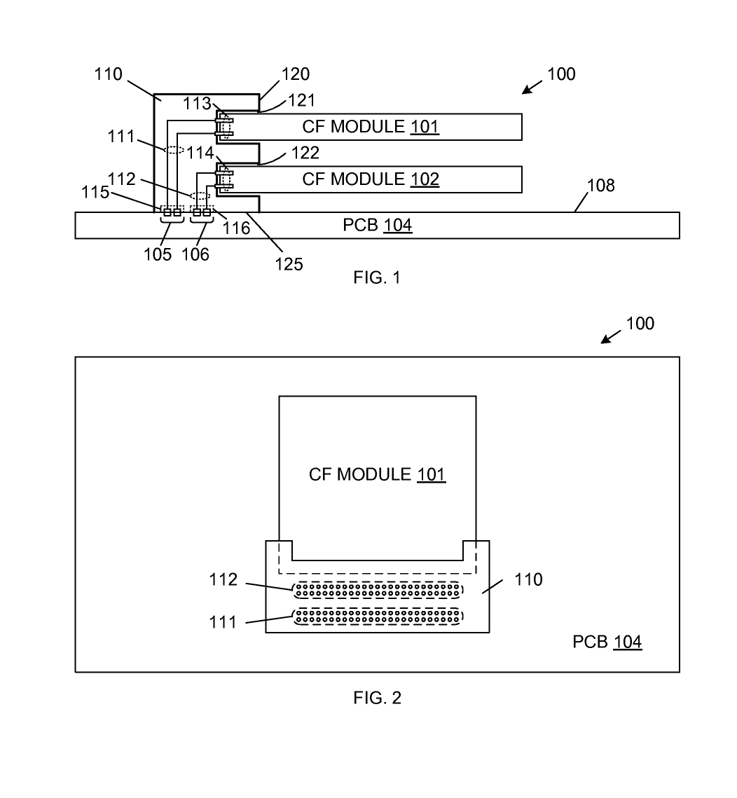

FIG. 1 is a cross sectional side view of a PCB system 100 that implements a double-stacked memory card concept in accordance with one embodiment of the present invention. PCB system 100 includes electronic modules 101-102, PCB 104 and housing element 110. In the illustrated embodiments, electronic modules 101-102 are memory cards, such as compact flash modules. However, it is understood that other types of memory cards or electronic modules can be used in other embodiments. Housing element 110 is mounted on the upper surface 108 of PCB 104. Housing element 110 can be attached to PCB 104, for example, by an adhesive and/or one or more mechanical fasteners (e.g., screws).

Housing element 110 includes openings/slots 121 and 122, which are formed in a vertical surface 120 of housing element 110, and which are sized to receive compact flash modules 101 and 102, respectively, as illustrated by FIG. 1. In accordance with one embodiment, compact flash modules 101 and 102 are positioned in parallel with one another when inserted into slots 121 and 122.

Housing element 110 also includes a first set of internal conductors/signal wires 111, which extend between slot 121 and a lower horizontal surface 125 of housing element 110, and a second set of internal conductors/signal wires 112, which extend between slot 122 and the lower surface 125 of housing structure. A first set of male connector elements (e.g., pins) 113 are connected to ends of the first set of internal conductors 111, wherein these connector elements 113 extend into slot 121. Similarly, a second set of male connector elements 114 are connected to ends of the second set of internal conductors 112, wherein these connector elements 114 extend into slot 122. When compact flash modules 101 and 102 are inserted into the slots 121 and 122 of housing element 110, female connector elements of compact flash modules 101 and 102 engage with the first and second sets of male connector elements 113 and 114, respectively. Note that housing element 110 provides mechanical support for the compact flash modules 101-102. Housing element 110 may be short, thereby providing minimal support, or may substantially enclose the compact flash modules 101-102. Although the present invention is described using an embodiment where male connector elements are located in the housing element 110 and female connector elements are located in the memory cards 101-102, it is understood that these connector element types can be reversed in other embodiments. Moreover, it is understood that other connector types may be utilized in other embodiments.

A first set of surface connector elements 115 are connected to ends of the first set of internal conductors 111 at the lower surface 125 of housing element 110. Similarly, a second set of surface connector elements 116 are connected to ends of the second set of internal conductors 112 at the lower surface 125 of housing element 110. When the housing element 110 is attached to PCB 104, the first and second sets of connector elements 115 and 116 are placed into electrical contact with sets of conductive elements (traces) 105 and 106, respectively of PCB 104. The first and second sets of connector elements 115-116 can be either press fit or surface mounted to the corresponding sets of conductive elements (traces) 105-106 on PCB 104. In accordance with one embodiment of the present invention, memory cards 101 and 102 are positioned in parallel with the upper surface 108 of PCB 104 when memory cards 101-102 are inserted into housing element 110.

In the manner described above, the first set of internal conductors 111, the first set of male connector elements 113 and the first set of surface connector elements 115 provide electrical connections between memory card 101 and traces 105 of PCB 104. Similarly, the second set of internal conductors 112, the second set of male connector elements 114 and the second set of surface connector elements 116 provide electrical connections between memory card 102 and traces 106 of PCB 104.

FIG. 2 is a top view of PCB system 100 that shows compact flash module 101, housing element 110 and PCB 104. Compact flash module 102 is aligned with and located under compact flash module 101, and is therefore not visible in the top view of FIG. 2. Although compact flash modules 101-102 are vertically aligned in FIGS. 1-2, thereby minimizing the area over PCB 104 covered by these modules 101-102, it is understood that embodiments wherein the positions of the modules 101-102 are shifted relative to one another are also considered to fall within the scope of the present invention. FIG. 2 shows a cross sectional view of the vertically extending portions of the first and second sets of internal conductors 111 and 112, in accordance with one embodiment of the present invention. In the illustrated embodiment, the sets of internal conductors 111 and 112 are fully independent. In this embodiment, compact flash module 101 may be accessed by a first controller/processor via traces 105, and compact flash module 102 may be accessed by a second (independent) controller/processor via traces 106, wherein these controller/processors are either located on PCB 104, or are coupled to PCB 104. In this manner, housing element 110 provides access to two independent memory cards 101-102, while requiring a relatively small layout area on PCB 104.

Alternately, there may be varying degrees of sharing between the signal lines of the individual compact flash cards 101-102 to minimize the PCB footprint.

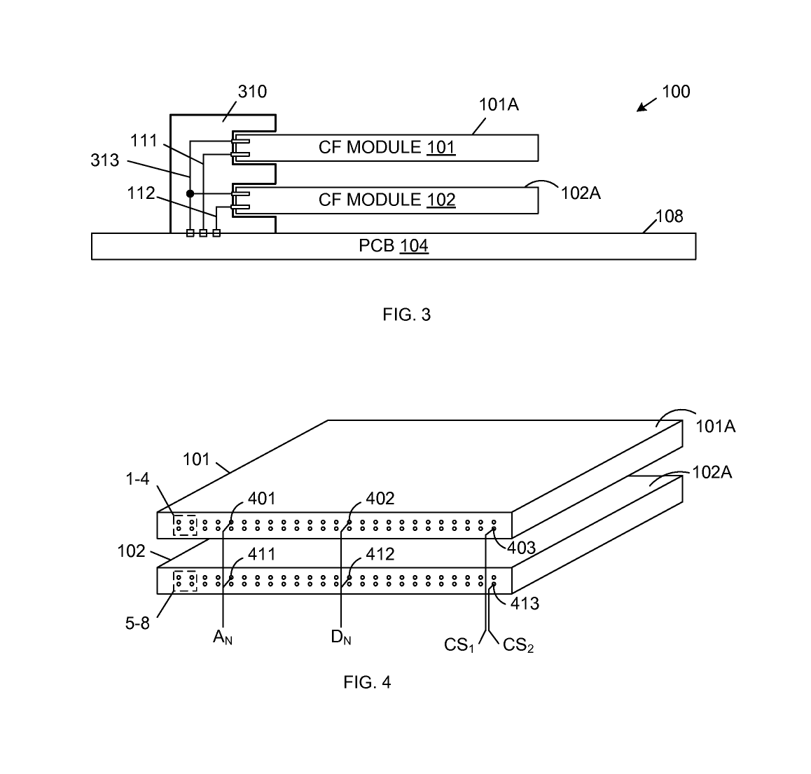

FIG. 3 is a cross sectional side view of a PCB system 300 that implements a double-stacked memory card concept in accordance with one variation of the above-described embodiments. PCB system 300 includes memory cards 101-102, PCB 104 and housing element 310. Housing element 310 is similar to housing element 110 (FIG. 1), with differences noted below. In addition to the first and second sets of internal conductors 111 and 112, housing element 310 includes a third set of one or more internal conductors 313, wherein the third set of internal conductors 313 are commonly connected to both of the compact flash modules 101 and 102. Thus, signals on the third set of internal conductors 313 are provided to both compact flash modules 101 and 102.

In accordance with one embodiment, compact flash modules 101 and 102 are oriented in the same manner with respect to housing element 310 (or housing element 110). For example, as illustrated in FIG. 3, a ‘top’ surface 101A of compact flash module 101 is facing away from PCB 104, and a ‘top’ surface 102A of compact flash module 102 is also facing away from PCB 104, such that the female connector elements of compact flash modules 101 and 102 have the same orientation over PCB 104. FIG. 4 is an isometric view of compact flash modules 101-102, which illustrates the orientation of the associated female connector elements when these modules 101-102 are positioned in housing module 310 with the top surfaces 101A and 102A facing away from PCB 104. As illustrated by FIG. 4, female connector elements 401, 402 and 403 of compact flash module 101 are vertically aligned with the corresponding female connector elements 411, 412 and 413, respectively, of compact flash module 102 when modules 101-102 are fitted into housing element 310. The corresponding connector elements 401 and 411, 402 and 412, and 403 and 413 carry signals having the same specification/function in compact flash modules 101 and 102, respectively. For example, corresponding connector elements 401 and 411 may carry the N^{th} bit of an address value A_{N} used to address compact flash modules 101 and 102, respectively. Corresponding connector elements 402 and 412 may carry the N^{th} bit of a data value D_{N} read from/written to compact flash modules 101 and 102, respectively. Corresponding connector elements 403 and 413 may carry chip select signals CS₁ and CS₂ (or other control signals such as write enables or reset signals) to compact flash modules 101 and 102, respectively.

Orienting the connector elements of compact flash modules 101 and 102 in this manner allows connector elements having similar functions to be easily connected to a shared signal wire within housing element 310. In accordance with one embodiment, corresponding address and data connector elements in compact flash modules 101 and 102 are connected to shared signal wires within housing element 110, while certain connector elements that carry control signals specific to the modules 101 and 102 (such as chip select signals CS₁ and CS₂) are connected to independent signal wires within housing element 110. (See, FIG. 4.) Stated another way, that the chip select signal CS₁ is transmitted on a signal wire included in the first set of internal conductors 111, the chip select signal CS₂ is transmitted on a signal wire included in the second set of internal conductors 112, and the address signal A_{N} and data signal D_{N} are transmitted on signal wires included in the third set of internal conductors 313.

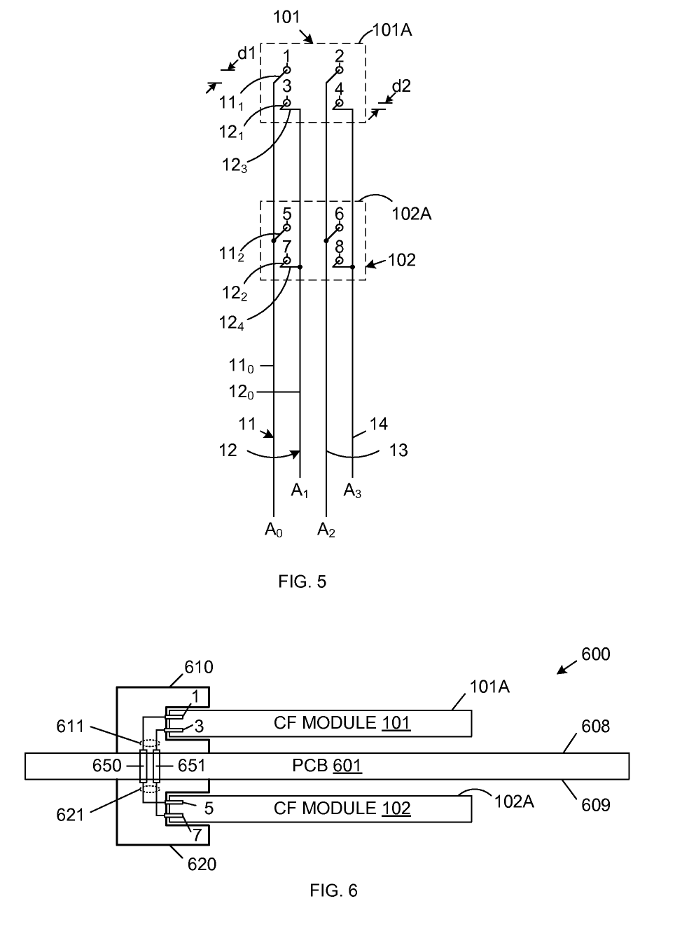

As also illustrated by FIG. 4, compact flash module 101 includes female connector elements 1-4, which are vertically aligned with female connector elements 5-8. FIG. 5 is a close-up view of female connector elements 1-4 of compact flash card 101 and female connector elements 5-8 of compact flash card 102, along with the signal lines 11-14 within housing element 310 that are used to electrically connect these vertically aligned female connector elements. As illustrated by FIG. 5, signal line 11 carries an address signal A₀ to female connector element 1 of module 101 and to the vertically aligned female connector element 5 of module 102. Signal line 12 carries an address signal A₁ to female connector element 3 of module 101 and to vertically aligned female connector element 7 of module 102. Signal line 13 carries an address signal A₂ to female connector element 2 of module 101 and to vertically aligned female connector element 6 of module 102. Signal line 14 carries an address signal A₃ to female connector element 4 of module 101 and to vertically aligned female connector element 8 of module 102.

Signal line 11 includes a vertical portion 11₀ and two horizontal portions 11₁ and 11₂, each of which extends a first distance d1 from the vertical portion 11₀ to the corresponding female connector elements 1 and 5. All signal lines connecting female connector elements in the upper rows of female connector elements in modules 101 and 102 are substantially identical. Thus, signal line 13 is substantially identical to signal line 11 in the illustrated embodiment.

Signal line 12 includes a vertical portion 12₀, two horizontal portions 12₁-12₂, which are coupled to female connector elements 3 and 7, respectively, and two lateral portions 12₃-12₄, which join horizontal portions 12₁-12₂ to vertical portion 12₀. Each of the horizontal portions 12₁-12₂ extend a second distance d2 from the female connector elements 3 and 7, wherein the second distance d2 is less than the first distance d1. Lateral portions 12₃-12₄ extend laterally from horizontal portions 12₁-12₂, respectively, thereby providing separation between signal lines 11 and 12. More specifically, lateral portions 12₃-12₄ allow the vertical portion 12₀ of signal line 12 to be separated from the horizontal portion 11₂ of signal line 11.

All signal lines connecting female connector element in the lower rows of female connector elements in modules 101 and 102 are substantially identical. Thus, signal line 12 is substantially identical to signal line 14 in the illustrated embodiment.

Although specific signal lines 11-14 have been shown for connecting the female connector elements 1-4 and 5-8 of modules 101 and 102, it is understood that the arrangement of these signal lines could be modified by one of ordinary skill in the art, and that such modifications are considered to fall within the scope of the present invention. For example, the general construction of signal lines 11 and 12 could be swapped in an alternate embodiment. Moreover, although signal line 12 is shown as having horizontal portions 12₁-12₂ and lateral portions 12₃-12₄, it is understood that these portions could be replaced by portions that extend diagonally from the female connector elements 3 and 7 to the vertical portion 12₀. It is further understood that these portions 12₁-12₄ could be replaced by one or more portions that curve between the female connector elements 3 and 7 and the vertical portion 12₀. Moreover, although only signal lines 12 and 14 are shown to have lateral portions (e.g., 12₃-12₄) in the embodiment of FIG. 5, it is understood that all signal lines 11-14 could include such lateral portions in alternate embodiments. Thus, while particular vertical, horizontal and lateral conductor elements have been illustrated in FIG. 5, it is understood that there are multiple ways of connecting and arranging the signal lines within the housing element, and that these ways are considered to fall within the scope of the present invention.

In addition, although the female connector elements of compact flash modules 101-102 are vertically aligned in FIGS. 3-5, it is understood that in alternate embodiments, the positions of these female connector (and modules 101-102) may be shifted relative to one another.

FIG. 6 is a cross sectional side view of a PCB system 600 in accordance with an alternate embodiment of the present invention. PCB system 600 includes compact flash modules 101-102 (which are described above), PCB 601, and housing units 610 and 620. Housing unit 610, which is located on an upper surface 608 of PCB 601, receives compact flash module 101, such that the top surface 101A of this module is facing away from PCB 601. Housing unit 620, which is located on a lower surface 609 of PCB 601, receives compact flash module 102, such that the top surface 102A of this module is located adjacent to the lower surface 609 of PCB 601. Housing elements 610 and 620 are aligned with one another on PCB 601, such that the compact flash modules 101-102 of FIG. 6 have the same orientation described above in connection with FIGS. 1-5.

Upper housing element 610 includes a set of signal lines 611 that electrically couple compact flash module 101 to conductive traces on PCB 601 in the manner described above. Similarly, lower housing element 620 includes a set of signal lines 621 that electrically couple compact flash module 102 to conductive elements on PCB 601. The pinout of the set of signal lines 611 on the upper surface 608 of PCB 601 is a mirror image of the pinout of the set of signal lines 621 on the lower surface 609 of PCB 601. As a result, signal lines of corresponding signals of compact flash modules 101 and 102 are vertically aligned through PCB 601 (in the same manner illustrated by FIGS. 4 and 5). Consequently, corresponding signal lines of compact flash modules 101 and 102 can be electrically connected by vertical conductive vias formed through PCB 601. In the example illustrated by FIG. 6, a vertical conductive via 650 formed through PCB 601 is connected to a signal line in upper housing element 610, which in turn, is coupled to the female connector element 1 of compact flash module 101. Vertical conductive via 650 is also connected to a signal line in lower housing element 620, which in turn, is coupled to the female connector element 5 of compact flash module 102. Conductive via 650 thereby efficiently provides a shared connection between the vertically aligned connector elements 1 and 5 of compact flash modules 101 and 102. An address signal (A₀) provided to conductive via 650 (e.g., from a controller/processor mounted on, or coupled to, PCB 601) is therefore transmitted to female connector elements 1 and 5 of compact flash modules 101 and 102, respectively.

In a similar manner, vertical conductive via 651 facilitates a common electrical connection between the vertically aligned connector elements 3 and 7 of compact flash modules 101 and 102.

Although not illustrated in FIG. 6, it is understood that conductive traces on PCB 601 may also provide individual connections to signal lines located in housing elements 610 or 620 (e.g., signal lines that carry chip selects, write enables and resets). For example, PCB 601 may include a first trace that is connected to a signal line within housing element 610 that provides a connection to the female connector element 403 of compact flash module 101, wherein this first trace provides the chip select signal CS₁ to compact flash module 101.

Although the present invention has been described in connection with several specific embodiments, it is understood that variations of these embodiments are considered to fall within the scope of the invention. For example, although the present invention has been described in connection with dual stacked compact flash modules, it is understood that the present invention can be expanded to include more than two stacked compact flash modules. In addition, it is understood that the present invention can be applied to other types of memory modules (or other types of electronic modules). Accordingly, the present invention is only intended to be limited by the following claims.

We claim:

1. A connector element for transmitting signals between a printed circuit board, a first electronic module and a second electronic module, the connector element comprising:
a housing element having a first slot sized to receive the first electronic module, a second slot sized to receive the second electronic module, and a first surface for attachment to the printed circuit board; and
a first set of conductive elements for transmitting signals between the printed circuit board, the first electronic module and the second electronic module, wherein the first set of conductive elements extend through the housing element, wherein each of the conductive elements of the first set extend from the first surface to both the first slot and the second slot, wherein each of the conductive elements of the first set establishes a common electrical path for transmitting a signal between the first surface, the first slot and the second slot.

2. The connector element of claim 1, wherein the first set of conductive elements includes conductive elements for transmitting data signals to and from the first and second electronic modules.

3. The connector element of claim 1, wherein the first set of conductive elements includes conductive elements for transmitting address signals to the first and second electronic modules.

4. The connector element of claim 1, further comprising a second set of conductive elements for transmitting signals between the printed circuit board and the first electronic module, wherein the second set of conductive elements extend through the housing element, wherein each of the conductive elements of the second set extend from the first surface to the first slot, but not the second slot, wherein each of the conductive elements of the second set establishes a dedicated electrical path for transmitting a signal between the first surface and the first slot.

5. The connector element of claim 4, wherein the second set of conductive elements include at least one conductive element for transmitting a signal for selecting the first electronic module.

6. The connector element of claim 4, further comprising a third set of conductive elements for transmitting signals between the printed circuit board and the second electronic module, wherein the third set of conductive elements extend through the housing element, wherein each of the conductive elements of the third set extend from the first surface to the second slot, but not the first slot, wherein each of the conductive elements of the third set establishes a dedicated electrical path for transmitting a signal between the first surface and the second slot.

7. The connector element of claim 6, wherein the second set of conductive elements include at least one conductive element for transmitting a signal for selecting the first electronic module, and wherein the third set of conductive elements include at least one conductive element for transmitting a signal for selecting the second electronic module.

8. The connector element of claim 1, wherein the first slot is positioned in parallel with the second slot.

9. The connector element of claim 1, wherein the first surface of the housing element is positioned in parallel with the first and second slots.

10. The connector element of claim 1, further comprising:
a first set of connector elements located in the first slot and electrically coupled to the first set of conductive elements; and
a second set of connector elements located in the second slot and electrically coupled to the first set of conductive elements.

11. The connector element of claim 10, further comprising:
a third set of connector elements coupled to the first set of conductive elements, wherein the third set of connector elements are exposed at the first surface of the housing element.

12. A system comprising:
a printed circuit board;
a first electronic module;
a second electronic module; and
a connector element including:
a housing element having a first slot in which the first electronic module is engaged, a second slot in which the second electronic module is engaged, and a first surface engaged with the printed circuit board; and
a first set of conductive elements for transmitting signals between the printed circuit board, the first electronic module and the second electronic module, wherein the first set of conductive elements extend through the housing element, wherein each of the conductive elements of the first set extend from the first surface to both the first slot and the second slot, wherein each of the conductive elements of the first set establishes a common electrical path for transmitting a signal between the printed circuit board, the first electronic module and the second electronic module.

13. The system of claim 12, wherein the first set of conductive elements transmit address and data signals to the first and second electronic modules.

14. The system of claim 12, wherein the connector element further comprises a second set of conductive elements for transmitting signals between the printed circuit board and the first electronic module, wherein the second set of conductive elements extend through the housing element, wherein each of the conductive elements of the second set extend from the first surface to the first slot, but not the second slot, wherein each of the conductive elements of the second set establishes a dedicated electrical path for transmitting a signal between the printed circuit board and the first electronic module.

15. The system of claim 14, wherein the connector element further comprises a third set of conductive elements for transmitting signals between the printed circuit board and the second electronic module, wherein the third set of conductive elements extend through the housing element, wherein each of the conductive elements of the third set extend from the first surface to the second slot, but not the first slot, wherein each of the conductive elements of the third set establishes a dedicated electrical path for transmitting a signal between the printed circuit board and the second electronic module.

16. The system of claim 12, wherein the first electronic module and the second electronic module are stacked on top of each other over a surface of the printed circuit board.

17. The system of claim 16, wherein the first electronic module and the second electronic module are positioned in parallel with each other and the surface of the printed circuit board.

18. A method comprising:
inserting a first electronic module into a first slot in a housing element mounted on a first surface of a printed circuit board; and
inserting a second electronic module into a second slot in the housing element;
transmitting a first set of signals from the printed circuit board to both the first electronic module and the second electronic module, wherein the first set of signals are transmitted on a first set of conductive elements that extend through the housing element;
transmitting a first signal from the printed circuit board to the first electronic module, but not the second electronic module, wherein the first signal is transmitted on a first conductive element that extends through the housing element; and
transmitting a second signal from the printed circuit board to the second electronic module, but not the first electronic module, wherein the second signal is transmitted on a second conductive element that extends through the housing element.

19. The method of claim 18, wherein the housing element positions the first electronic module and the second electronic module in parallel with the first surface of the printed circuit board.

20. The method of claim 19, wherein the housing element positions the first electronic module and the second electronic module such that second electronic module is stacked between the first electronic module and the first surface of the printed circuit board.
